(19) United States
(12) Patent Application Publication
(10) Pub. No.: US 2026/0293185 A1
(43) Pub. Date: Sep. 24, 2026

(54) METAL-TO-TWO-DIMENSIONAL MATERIAL INTERFACE FOR TRANSISTORS AND METHOD FOR FABRICATING SAME

(71) Applicant: Intel Corporation, Santa Clara, CA (US)

(72) Inventors: Mahmut Sami Kavrik, Portland, OR (US); Uygar E. Avci, Portland, OR (US); Kevin P. O'Brien, Portland, OR (US); Andrey Vyatskikh, Hillsboro, OR (US); Jennifer Lux, Hillsboro, OR (US); Rupak Thapa, Hillsboro, OR (US); Carly Rogan, North Plains, OR (US)

(73) Assignee: Intel Corporation, Santa Clara, CA (US)

(21) Appl. No.: 19/087,792

(22) Filed: Mar. 24, 2025

(51) Int. Cl. H10D 30/47; H10D 30/01; H10D 62/80; H10D 64/62; H10D 64/68

(52) U.S. Cl. CPC H10D 30/481; H10D 30/017; H10D 62/883; H10D 64/62; H10D 64/691

(57) ABSTRACT

A metal-to-two-dimensional material interface for transistors; the apparatus and method for fabricating same. The apparatus comprises a first layer comprising transition metal atoms and chalcogen atoms. The first has an upper surface and a lower surface, the lower surface is overlaid on a substrate material comprising an oxide. A metal layer is overlaid directly on the upper surface. The metal layer includes at least ruthenium (Ru). The upper surface and the metal layer form an interface. The interface is abrupt, defined as having no voids, no carbon atoms, and no carbon interlayer.

### BACKGROUND

Some next-generation CMOS technology nodes seek to implement a two-dimensional (2D) material (also sometimes called a monolayer) in the channel regions of transistors. The 2D material can be vulnerable to undesirable defects during various stages of fabrication. Accordingly, it is desirable to improve the architecture of the metal-to-2D material interface for transistor devices and the process to fabricate the architecture.

### BRIEF DESCRIPTION OF THE DRAWINGS

FIG. 1 provides several simplified cross-sectional images of a metal-to-2D material interface, in accordance with any of the embodiments disclosed herein.

FIGS. 2A and 2B are simplified cross-sectional images showing the metal layer formed directly on the 2D material, and the channel lithography added (photoresist in regions to protect from oxygen plasma exposure), in the fabrication of a transistor, in accordance with any of the embodiments disclosed herein.

FIG. 2C is a simplified top-down or plan view of the image in FIG. 2B.

FIG. 3A is simplified cross-sectional image showing a stage in the fabrication of the transistor after a Tungsten (W) etch that leaves W at two source/drain regions, and otherwise the upper surface comprises ruthenium (Ru), in accordance with any of the embodiments disclosed herein.

FIG. 3B is a simplified top-down or plan view of the image in FIG. 3A.

FIG. 3C is simplified cross-sectional image showing a stage in the fabrication of the transistor after Ru etch and Hf oxidation that leaves the tri-layer metal layer at the two source/drain regions, and otherwise the upper surface comprises oxidized Hf, in accordance with any of the embodiments disclosed herein.

FIG. 3D is a simplified top-down or plan view of the image in FIG. 3C.

FIG. 4A and FIG. 4B depict an iso-lithography stage in the fabrication of the transistor based on the embodiment in FIG. 3C.

FIG. 5A depicts an iso-etch stage in the fabrication of the transistor based on the embodiment in FIG. 4B.

FIG. 5B illustrates the embodiment described in FIG. 5A after a device back gate stage in the fabrication of the transistor with the architecture of the metal-to-2D material interface, in accordance with any of the embodiments disclosed herein.

FIGS. 6A, 6B, and 6C illustrate an alternative method for making the architecture of the metal-to-2D material interface, in which H2 plasma is applied to an oxide layer to form a metal gate, in accordance with any of the embodiments disclosed herein.

FIG. 7 is an example method for making embodiments described herein.

FIG. 8 is a top view of a wafer and dies that may be included in a microelectronic assembly, in accordance with any of the embodiments disclosed herein.

FIG. 9 is a cross-sectional view of an integrated circuit device that may be included in any of the microelectronic assemblies disclosed herein.

FIGS. 10A-10D are perspective views of example planar, FinFET, gate-all-around, and stacked gate-all-around transistors.

FIG. 11 is a cross-sectional view of an integrated circuit device assembly that may include a microelectronic assembly, in accordance with any of the embodiments disclosed herein.

FIG. 12 is a block diagram of an example electrical device that may include a microelectronic assembly, in accordance with any of the embodiments disclosed herein.

### DETAILED DESCRIPTION

Some next-generation CMOS technology nodes seek to implement a two-dimensional (2D) material (also sometimes called a monolayer) for the channel regions. The 2D materials can be 1-3 atoms thick, with a thickness in the range of 0.6-0.7 nanometers (nm) per atomic layer. In various embodiments, the 2D material is based on using 3 atomic layers, therefore being in the range of 1.6 nm to 2.1 nm +/−10%. In other embodiments, the upper thickness of the 2D material can be 4 nanometers +/−10%. The 2D material possesses unique electronic and physical properties. There are several technical challenges to the realization of transistors using the 2D material.

A first technical challenge is that, due to the reduced, often sub-nanometer thickness of the 2D material, the 2D material requires a high quality and highly uniform surface to be formed on. One solution is to utilize sapphire wafers to grow the high quality 2D materials on, because sapphire wafers have a highly uniform surface. Yet, other characteristics of sapphire, such as its transparency, insulator characteristics, and its high costs, make it unsuitable for device fabrication or as a body/substrate material.

Another approach is to grow the 2D material on a sapphire substrate and then transfer the 2D material to a conventional substrate, such as a silicon (Si) substrate, for device fabrication. The transfer of the 2D material can be performed using a polymer or photoresist for transfer, for example, polystyrene or a polymer thermal release tape, such as a poly methyl methacrylate (PMMA). The polymer thermal release tape can be applied to an upper surface of the 2D material (with the lower surface of the 2D material being on the sapphire substrate) and then the 2D material can be peeled off of the sapphire with the polymer thermal release tape. However, this process leaves an undesirable residue on the 2D material after the transfer completion. Additionally, this transfer procedure can introduce an unknown level of defects, such as dangling bonds on the 2D surface, or voids on the 2D surface, extending into the 2D material.

Another technical problem in using the polymer thermal release tape transfer process is that lithography induces sub-nm residual carbon on the 2D material. Due to the sensitivity of the 2D materials to oxygen, plasma, and UV light in transistor fabrication, the residual carbon results in the formation of a film of carbon, called a carbon interlayer, between the 2D materials and the gate oxide. The carbon interlayer deteriorates device performance by inducing an interface trap charge and oxide trap charges; these trap charges can adversely result in a voltage threshold (Vt) shift, hysteresis, and the pinning of the fermi level in the transistor device.

Another technical challenge is related to the fabrication process. In available transistor fabrication approaches, the 2D material is overlaid with a metal layer in the source/drain (S/D) regions. Due to the high contact resistance between 2D material and the metal of the S/D, a gate-first flow is not adopted in transistor fabrication, therefore S/D lithographic patterning in the first step can adversely expose both the S/D regions and the channel regions of the transistors to photoresist. For at least these reasons, it is necessary to improve the architecture of the metal-to-2D material interface for transistor devices and the process to fabricate the architecture.

Embodiments provide a technical solution to this technical problem. The proposed architecture and methods provide an interface between the metal and the 2D material that does not have (excludes) the carbon and the voids caused by the polymer thermal release tape-induced surface damage and defects to the gate oxide. Embodiments form a metal layer (in various embodiments, a tri-layer metal, or metal stack) directly on the 2D material, prior to transfer. The metal layer or metal stack is that which will be used for the transistor fabrication. In one non-limiting example, the metal layer includes three sublayers, hafnium/ruthenium/tungsten (Hf/Ru/W), which are deposited on a 2D material comprising tungsten diselenide (WSe2) directly, after which the resulting architecture comprising the metal layer-2D material is then used for 2D transfer onto a hafnium oxide (HfO2) back-gated substrate. Embodiments also support an NMOS transistor option, in which the metal stack may Sb/Hf/Ru/W, as an example.

Fabrication may then proceed, and the metal stack is used for transistor device fabrication with selective oxidation, as described in more detail below. Advantageously, the method places the 2D material in contact with the final metals (that will be part of the transistor) from the beginning of the transfer process, thereby eliminating in the resulting architecture any carbon or other contaminations that may be introduced by the 2D transfer process, as well as protecting the 2D material from any fabrication-induced defects by sealing/covering the 2D material throughout the fab process.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

Certain terminology may also be used herein for the purpose of reference only and thus are not intended to be limiting. For example, terms such as “upper,” “lower,” “above,” “below,” “bottom,” and “top” refer to directions on the page in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

Reference is now made to the drawings, which are not necessarily drawn to scale, wherein similar or same numbers may be used to designate same or similar parts in different figures. The drawings illustrate generally, by way of example, but not by way of limitation, various embodiments discussed in the present document. It is to be understood that drawings illustrate idealized versions of structure cross-sections. In actual cross-sections, the lines, layers, and other elements illustrated in the drawings can have shapes that vary from those illustrated. For example, surfaces illustrated as planar possess undulations, bumps, or dishing features; sidewalls can have a taper to them; ninety-degree corners can be rounded; and lines, layers, and features can overlap more or less than illustrated.

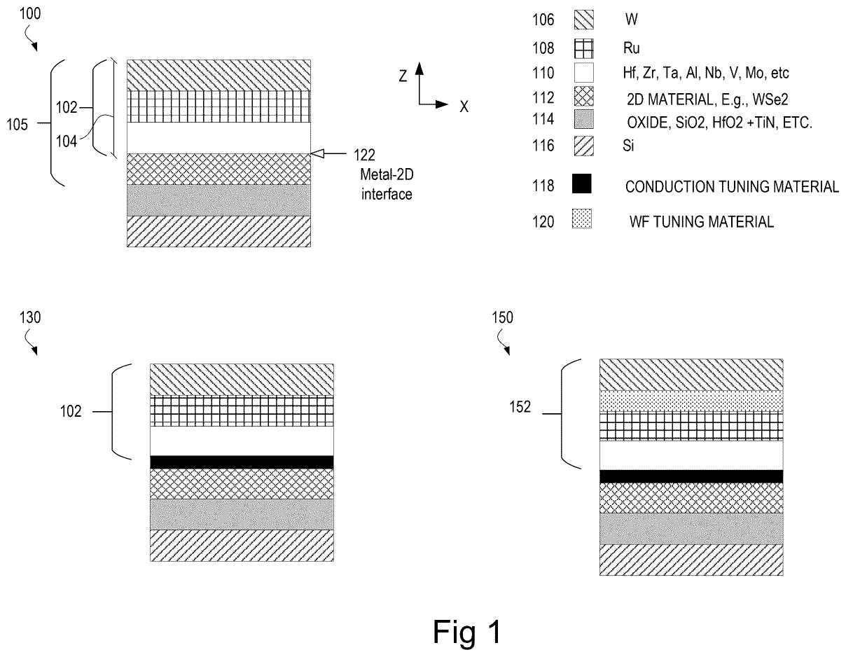

Turning now to FIG. 1, several simplified cross-sectional images show the architecture of a metal-to-2D material interface 122, in accordance with any of the embodiments disclosed herein. Embodiment 100 depicts a generalized metal layer 102, with a thickness 104 (measured in the Z direction in the figure) overlaid directly on a 2D material 112. The interface 122 is where the upper surface and the metal layer are directly in contact, as illustrated. The interface 122 is “abrupt,” defined as having no voids, no carbon atoms, and no carbon interlayer.

A substrate material 114 that comprises an oxide is below the 2D material 112. The substrate material 114 may be overlaid on a silicon 116 wafer, or another substrate material. The substrate material 114 may comprise silicon dioxide (SiO2), hafnium dioxide (HfO2) plus titanium nitride (TiN), or the like.

The 2D material 112 is the first layer overlaid on the substrate material 114, the 2D material 112 has an upper surface and a lower surface, and the metal layer 102 is overlaid directly on the upper surface of the 2D material. The metal layer 102 includes at least ruthenium (Ru). In various places herein, the structure or architecture 105 is an intermediate structure that includes the metal layer 102 plus the 2D material; architecture 105 may be transferred as one unit, using a polymer or PMMA applied on the upper surface of the metal layer.

In various embodiments, the metal layer 102 is further defined by at least a first sublayer 110 of a first metal and a second sublayer 108 of the ruthenium. Defined this way, the interface 122 includes the first sublayer 110 and the upper surface. In some embodiments, the first sublayer comprises hafnium (Hf). In other embodiments, the first sublayer includes one of zirconium (Zr), tantalum (Ta), aluminum (Al), niobium (Nb), vanadium (V), or molybdenum (Mo). The first sublayer comprises a thickness of 1 nanometer +/−10%, and the second sublayer (the ruthenium) comprises a thickness of 10 nanometers +/−10%.

In various embodiments, a third sublayer 106, which may be tungsten (W) is also included in the metal layer 102, overlaid on the second sublayer 108. The third sublayer 106 may have a thickness of 10 nanometers +/−10%. Accordingly, the metal layer 102 may also be referred to as a metal stack, or tri-layer metal.

As those with skill in the art will appreciate, the 2D material comprises transition metal atoms and chalcogen atoms. The 2D material may be between 0.6 nanometers +/−10% and 4 nanometers +/−10% thick. The 2D material may comprise molybdenum or tungsten. In various embodiments, the 2D material may comprise Tungsten diselenide (WSe2), Molybdenum diselenide (MoS2), Molybdenum ditelluride (MoTe2), Tungsten disulfide (WS2), or a similar material.

Additional materials can be added to the above-described layers to enable customization of the operation of the transistors built based on embodiment 100. For example, to tune the conductivity of the source/drain regions, a conduction tuning material 118 may be used at the interface, as shown in embodiment 130. The conduction tuning material 118 may comprise antimony (Sb). In another example, in embodiment 150, a work function (WF) tuning material 120 may be added between the second sublayer 110 and the third sublayer 106. The WF tuning material 120 may comprise platinum (Pt), or palladium (Pd) sandwiched between the second sublayer and the third sublayer.

The above-described flow is associated with the creation of a 2D FEOL (front end of line) CMOS transistor with a silicon back gate. In other embodiments, the metal to 2D material interface may be found in a BEOL (back end of line) metal back gate or local back gate (LBG) CMOS transistor. In various embodiments, the channel width may be equal to the width of the source and drain region.

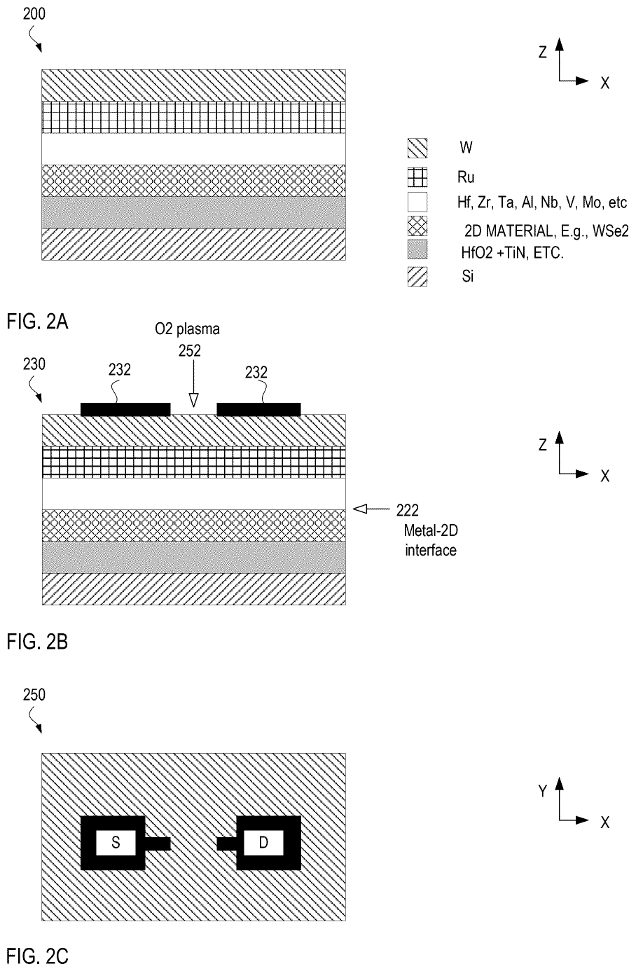

The architecture illustrated in FIG. 1 can be used to fabricate transistors, as illustrated in FIGS. 2A, 2B, 2C, 3A, 3B, 3C, 3D, 4A, 4B, 5A, 5B, and FIGS. 6A, 6B, and 6C, in which the shading of the layers is consistent with the shading described in connection with FIG. 1.

FIG. 2A embodiment 200 is analogous to embodiment 100. The metal layer is formed directly on the 2D material at the metal-2D interface 222. In a non-limiting example, the substrate material may be hafnium dioxide (HfO2) plus titanium nitride (TiN). In FIG. 2B, embodiment 230, the channel lithography is added (photoresist 232 is in regions to protect from oxygen plasma 252 exposure), in the fabrication of a transistor, in accordance with any of the embodiments disclosed herein.

FIG. 2C is a simplified top-down or plan view of the image in FIG. 2B. One of the photoresist 232 regions is associated with a source and one of the photoresist 232 regions is associated with a drain of the transistor.

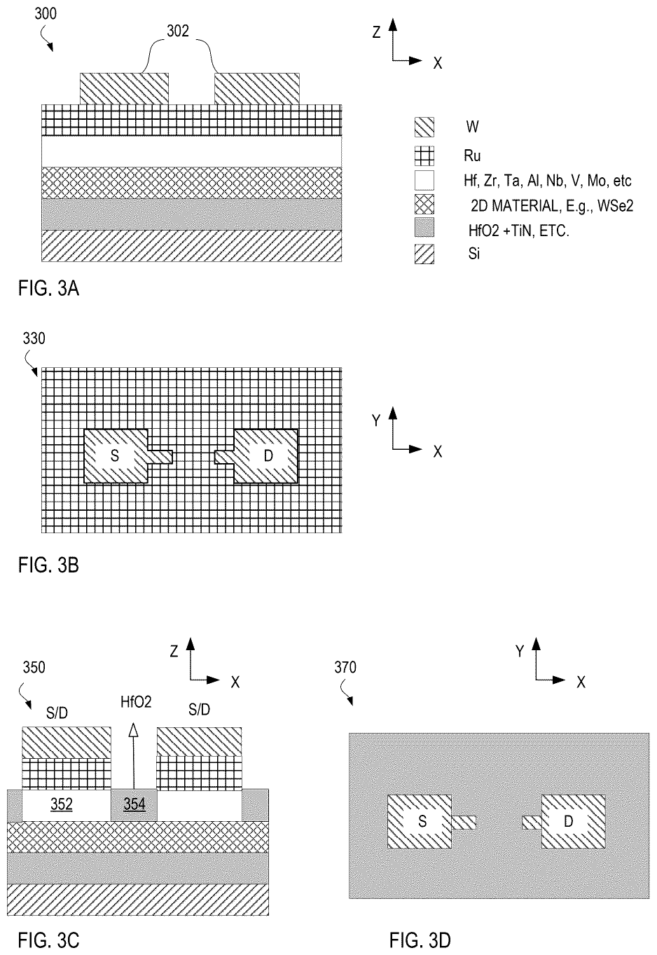

FIG. 3A embodiment 300 is simplified cross-sectional image showing a stage in the fabrication of the transistor after a Tungsten (W) etch that leaves W at the two source/drain regions 302, and otherwise the upper surface has been etched of W and the second sublayer, the ruthenium (Ru), in accordance with any of the embodiments disclosed herein. FIG. 3B embodiment 330 is a simplified top-down or plan view of the image in FIG. 3A.

FIG. 3C embodiment 350 is a simplified cross-sectional image showing a stage in the fabrication of the transistor after the ruthenium has been etched, leaving the two source/drain (S/D) regions that comprise the tri-layer metal. External to the S/D regions, the hafnium is oxidized (HfO2). The Hf oxidation leaves the tri-layer metal layer at the two source/drain regions, and otherwise the upper surface comprises oxidized Hf, as also illustrated in FIG. 3D.

Looking closely at embodiment 350, it may be described as follows: a first region 352 of the first sublayer has the second sublayer overlaid thereon, and a second region 354 of the first sublayer comprises an oxidized form of the first metal. In practice, the first region 352 is a source or drain region and the second region 354 is a gate region of the transistor.

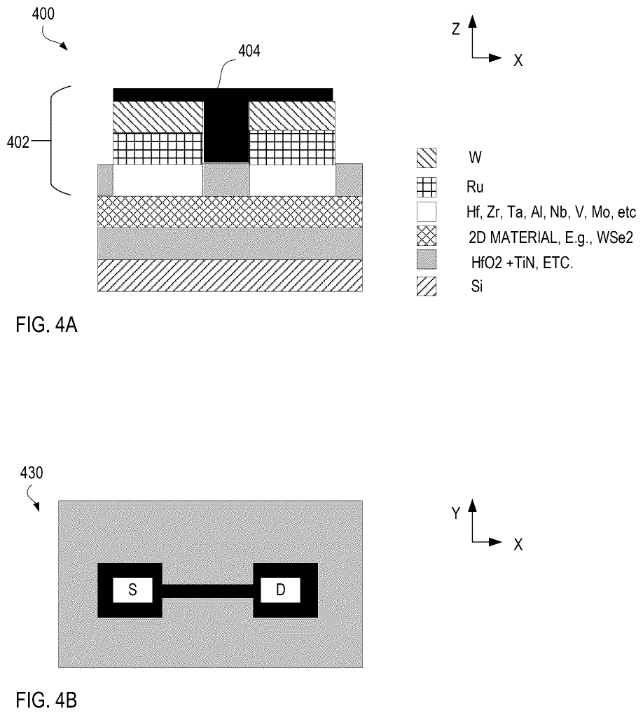

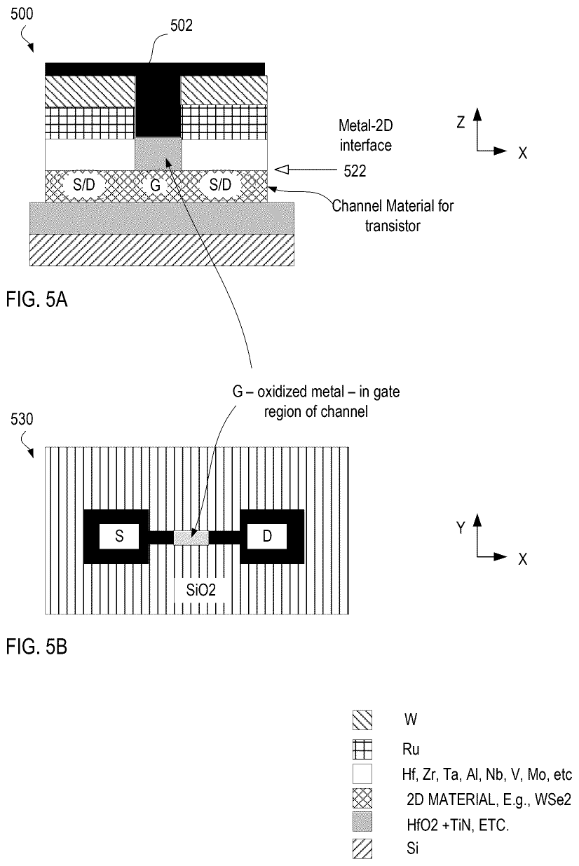

FIG. 4A and FIG. 4B depict an iso-lithography stage in the fabrication of the transistor based on the embodiment in FIG. 3C. In embodiment 400 and embodiment 430, a layer of photoresist 404 is overlaid on the transistor device that is formed in the metal stack/metal layer 402. FIG. 5A depicts an iso-etch stage in the fabrication of the transistor based on the embodiment in FIG. 4B. Iso-etch and iso-lithography are understood to be semiconductor processing stages as known by those with skill in the art.

In embodiment 500, after the iso-etch, the 2D material external to the transistor device is removed. FIG. 5B embodiment 530 illustrates the embodiment 500 after a device back gate stage in the fabrication of the transistor with the architecture of the metal-to-2D material interface, in accordance with any of the embodiments disclosed herein.

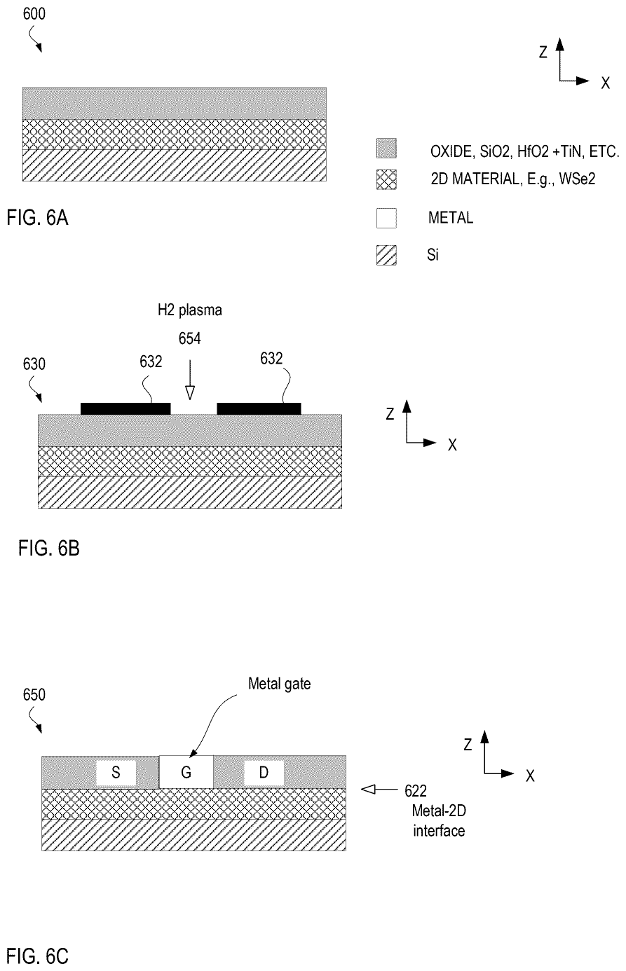

FIGS. 6A, 6B, and 6C illustrate an alternative method for making the architecture of the metal-to-2D material interface. In embodiment 600, an oxide layer is overlaid on the 2D material. FIG. 6B illustrates using photoresist to protect the S/D regions 632, as before, and this time H2 plasma is used. The H2 plasma converts the gate region of the oxide to a metal. Since the oxide layer was formed or deposited directly on the 2D material, the interface 622 has the same qualities described above: it is abrupt, it has no voids and no carbon atoms.

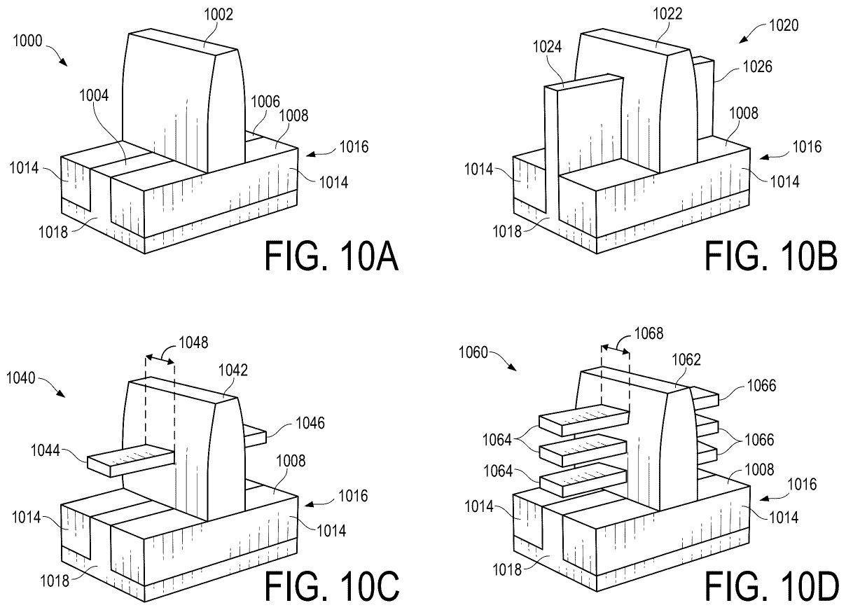

A field effect transistor (FET) device is described in more detail in connection with FIGS. 10A-10D. With reference to FIG. 5A and FIG. 5B, the FET using the metal-2D material interface described herein may comprise a two-dimensional (2D) material as a channel material. The channel material or 2D material initially defines a channel comprising a first source/drain region, a gate region, and a second source/drain region. The first sublayer of metal is overlaid directly on the channel, such that an interface 522 formed between the 2D material and the first sublayer of metal does not have carbon atoms. The first sublayer of metal is oxidized at the gate region (e.g., see embodiment 530). At the first source/drain region and at the second source/drain region, a second sublayer of metal is directly overlaid on the first sublayer of metal, and a third sublayer of metal is directly overlaid on the second sublayer of metal. In an embodiment, the second sublayer comprises ruthenium (Ru), and the third sublayer of metal comprises tungsten (W).

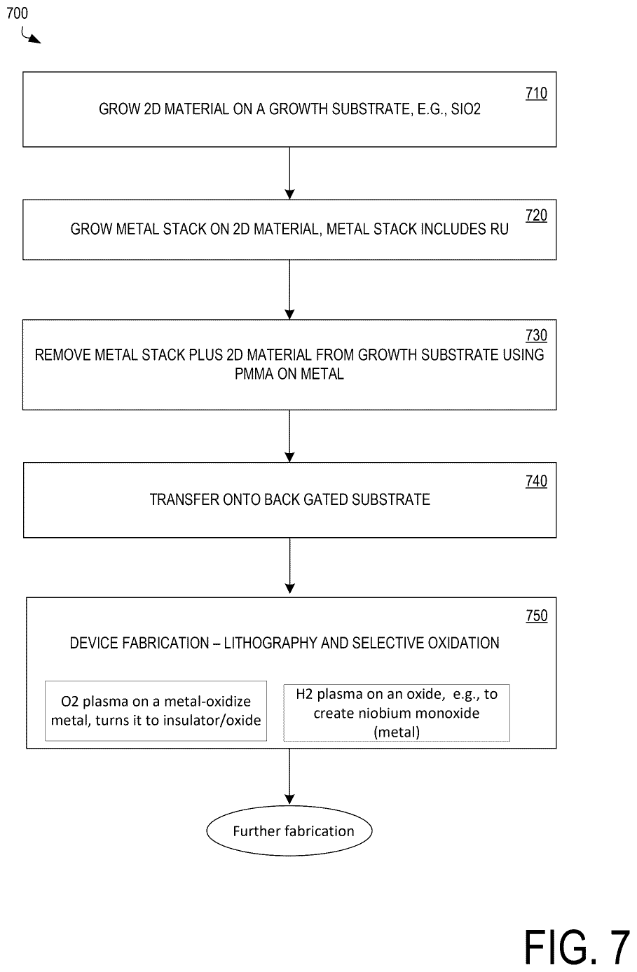

FIG. 7 is an example method 700 for making embodiments described herein. At 710, a 2D material is grown on a growth substrate. The growth substrate may be SiO2, or sapphire. The 2D material can be one of the 2D materials described above. At 720, the metal layer, or metal stack is grown or deposited directly on the 2D material. The interface formed between the metal layer and the 2D material, viewed as a cross-section in the Z plane, excludes carbon atoms, excludes a carbon interlayer, and excludes voids. Optionally, the interface may include antimony, as described in connection with FIG. 1.

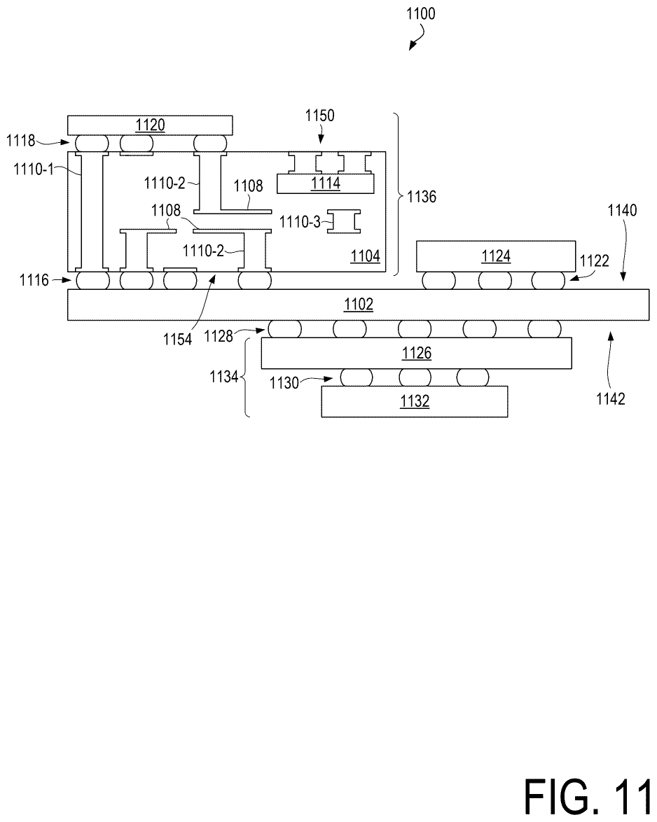

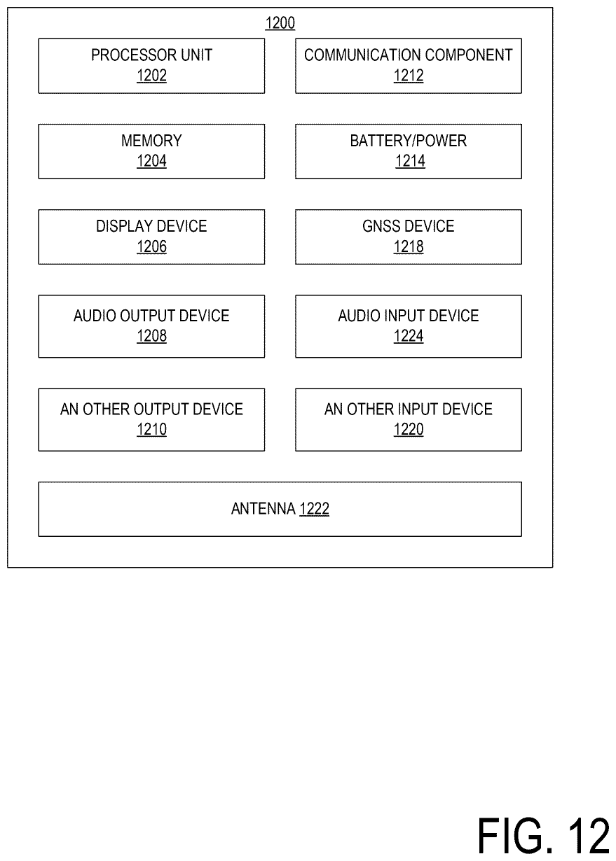

At 730, the structure or architecture that includes the metal layer plus the 2D material (e.g., architecture 105, FIG. 1) is removed from the growth substrate using, e.g., PMMA on the upper surface of the metal stack. At 740, the architecture 105 is transferred onto a back gated substrate. As mentioned above, the back gated substrate may be in a FEOL or in a BEOL stage of fabrication. At 750, device fabrication including lithography and selective oxidation is performed. Accordingly, at 750, the method includes identifying, for a plurality of field effect transistors, respective gate locations in the 2D channel material; and oxidizing the 2D channel material at the respective gate locations. In an embodiment, at 750, O2 plasma directed at the metal oxidizes the metal in the gate region and turns it into an insulator or oxide. In another embodiment, at 750, H2 plasma directed at an oxide creates a metal such as niobium monoxide at the gate region (FIGS. 6A-6C). The task at 750 thereby creates a plurality of 2D transistors. After 750, device fabrication may further proceed, such as, but not limited to, overlaying the plurality of 2D transistors with a layer comprising local interconnects, comprising, for the individual input/output signals associated with every transistor of the plurality of 2D transistors, metal contacts and traces, singulation of the plurality of 2D transistors into individual dies, adding solder bumps to dies, assembling dies into package assemblies (e.g., FIG. 11), overmolding package assemblies, providing thermal solutions to package assemblies, and eventually, soldering a package assembly into a final product (e.g., FIG. 12).

Thus, metal-to-2D material interface architectures and methods for making the same have been provided. Embodiments can be recognized using images focused on a cross-sectional area where the herein described metal-to-2D material interface with abrupt characteristic can be found. In particular, using XPS depth profiling, cross-sectional TEM imaging, and a corresponding compositional analysis to obtain the stoichiometry of the metal stack can reveal the practice of concepts described herein.

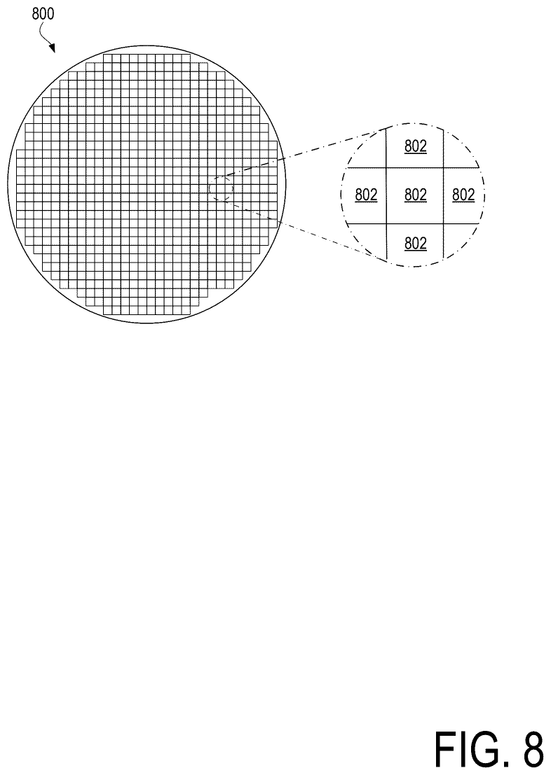

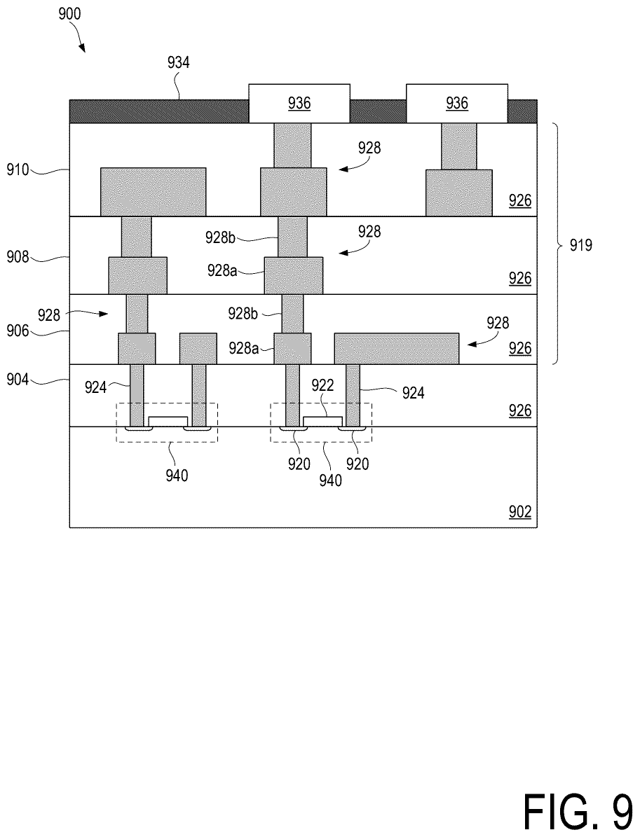

The following figures and description provide context and supporting information for the embodiments described above. FIG. 8 is a top view of a wafer 800 and dies 802 that may be included in any of the embodiments disclosed herein. The wafer 800 may be composed of semiconductor material and dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The dies 802 may be any of the dies disclosed herein. The dies 802 may include one or more transistors (e.g., transistors 940 of FIG. 9, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 800 or the dies 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Various ones of the microelectronic assemblies or apparatus' disclosed herein may be manufactured using a die-to-wafer assembly technique in which some dies are attached to a wafer 800 that include others of the dies, and the wafer 800 is subsequently singulated.

FIG. 9 is a cross-sectional view of an integrated circuit structure 900 that may be included in any of the embodiments disclosed herein. Multiple instances of the integrated circuit structure 900 may be included in the dies 802 (FIG. 8). The integrated circuit structure 900 may be formed on a die substrate 902).

The die substrate 902 may be a semiconductor substrate composed of semiconductor material including, for example, n-type or p-type materials (or a combination of both). The die substrate 902 may include, for example, a crystalline substrate formed using a bulk silicon or a silicon-on-insulator (SOI) substructure. In some embodiments, the die substrate 902 can comprise a layer of silicon on top of an SOI layer with bulk silicon below the SOI layer. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit structure 900 may be used. The die substrate 902 may be part of a singulated die (e.g., dies 802 of FIG. 8) or a wafer (e.g., wafer 800 of FIG. 8).

The integrated circuit structure 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, source and drain regions (S/D regions 920), a gate 922 to control current flow between the S/D regions 920, and S/D contacts 924 to route electrical signals to and from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

FIGS. 10A-10D are perspective views of example planar, FinFET, gate-all-around, and stacked gate-all-around transistors. The transistors illustrated in FIGS. 10A-10D are formed on a substrate 1016 having a substrate surface 1008 and a bulk region 1018. Isolation regions 1014 separate the source and drain regions of the transistors from other transistors.

FIG. 10A is a perspective view of an example transistor 1000 comprising a gate 1002 that controls current flow between a source region 1004 and a drain region 1006. The transistor 1000 is planar in that the source region 1004, the drain region 1006 and the substrate surface 1008 lie in the same plane.

FIG. 10B is a perspective view of an example transistor 1020 comprising a gate 1022 that controls current flow between a source region 1024 and a drain region 1026. The transistor 1020 is non-planar in that the source region 1024 and the drain region 1026 comprise “fins” that extend upwards from the substrate surface 1008. The transistor 1020 can be referred to as a FinFET. As the gate 1022 encompasses three sides of the fin that extends from the source region 1024 to the drain region 1026, the transistor 1020 can be considered a tri-gate transistor. FIG. 10B illustrates one S/D fin extending through the gate 1022, but multiple S/D fins can extend through the gate of a FinFET transistor.

FIG. 10C is a perspective view of a transistor 1040 comprising a gate 1042 that controls current flow between a source region 1044 and a drain region 1046. The transistor 1040 is non-planar in that the source region 1044 and the drain region 1046 lie in a different plane than the substrate surface 1008. As the gate 1042 encompasses all sides of the channel region of the transistor 1040 that extends from the source region 1044 to the drain region 1046, the transistor 1040 can be referred to as a gate-all-around (GAA) transistor.

FIG. 10D is a perspective view of a transistor 1060 comprising a gate 1062 that controls current flow between multiple elevated source regions 1064 and multiple elevated drain regions 1066. The transistor 1060 is a stacked GAA transistor as the gate controls the flow of current between multiple elevated S/D regions stacked on top of each other. The transistors 1040 and 1060 are considered gate-all-around transistors as the gates encompass all sides of the channel regions of the transistor that extends from the source regions to the drain regions. The transistors 1040 and 1060 can alternatively be referred to as nanowire, nanosheet, or nanoribbon transistors depending on the width (e.g., widths 1048 and 1068 of transistors 1040 and 1060, respectively) of the channel regions extending through the gate.

Returning to FIG. 9, transistors 940 may include a gate 922 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 10B, the gate electrode may have an upside-down U-shape that includes a top portion substantially parallel to the surface of the die substrate 902 and two side portions that are substantially perpendicular to the top surface of the die substrate 902. In other embodiments, such as the planar FET illustrated in FIG. 10A, at least one of the metal layers that form the gate electrode may be a planar layer that is substantially parallel to the top surface of the die substrate 902 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 920 may be formed within the die substrate 902 adjacent to the gate 922 of transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse further into the die substrate 902 may follow the ion implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or information-carrying signals (e.g., input/output (I/O) signals, may be routed to and/or from devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with interconnect structures 928 of the interconnect layers 906-910. The one or more interconnect layers 906-910 may form a metallization stack 919 (which can also be referred to as an “ILD stack” (inter-layer dielectric stack)) of the integrated circuit structure 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit structures having more or fewer interconnect layers than depicted.

In some embodiments, the interconnect structures 928 may include traces or lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, lines 928a of different interconnect layers 906-910 are electrically coupled by vias 928b.

The interconnect layers 906-910 may include a dielectric material 926 within which the interconnect structures 928 are disposed, as shown in FIG. 9. In some embodiments, dielectric material 926 in different ones of the interconnect layers 906-910 may have different compositions; in other embodiments, the composition of the dielectric material 926 between different interconnect layers 906-910 may be the same. The device layer 904 may include a dielectric material 926 within which the transistors 940 are disposed and upon which a bottom layer of the metallization stack is located. The dielectric material 926 that is part of the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (which can be referred to as a Metal 1 or “M1” layer) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (which can be referred to as a Metal 2 or “M2” layer) may be formed directly on the first interconnect layer 906. In some embodiments, the second interconnect layer 908 may include vias 928b to couple the lines 928a of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (which can be referred to as a Metal 3 or “M3” layer) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit structure 900 (i.e., farther away from the device layer 904) may be thicker than the interconnect layers that are lower in the metallization stack 919, with lines 928a and vias 928b in the higher interconnect layers being thicker than those in the lower interconnect layers.

The integrated circuit structure 900 may include a solder resist material 934 (e.g., polyimide or similar material) and conductive contacts 936 formed on the stack of interconnect layers 906-910. In FIG. 9, the conductive contacts 936 are illustrated as taking the form of bond pads. The conductive contacts 936 may be electrically coupled with interconnect structures 928 of the top-most layer in the metallization stack 919 and configured to route electrical signals between the transistors 940 and components external to the integrated circuit structure 900. For example, solder bonds may be formed on the conductive contacts 936 to mechanically and/or electrically couple an integrated circuit component comprising the integrated circuit structure 900 with another component (e.g., a printed circuit board). The integrated circuit structure 900 may include additional or alternate structures to route electrical signals from the interconnect layers 906-910; for example, the conductive contacts 936 may include other analogous features (e.g., posts) that can route the electrical signals between the transistors 940 and external components. The conductive contacts 936 may serve as the conductive contacts ### or ###, as appropriate.

In some embodiments in which the integrated circuit structure 900 is part of a double-sided die, the integrated circuit structure 900 may include a second metallization stack (not shown) located on the opposite side of the die substrate 902 from the device layer 904. This second metallization stack may include multiple interconnect layers as discussed above with reference to the interconnect layers 906-910. Through-silicon vias (TSVs) that extend through the die substrate 902 can provide electrically conductive pathways from the transistors 940 to the second metallization stack and the second metallizaton stack can electrically couple the TSVs to additional conductive contacts (not shown) located on the opposite side of the integrated circuit structure 900 from the conductive contacts 936.

In some embodiments, TSVs extending through the die substrate 902 can be used for routing power and ground signals from conductive contacts located on the opposite side of the integrated circuit structure 900 from the conductive contacts 936 to the transistors 940 and any other components integrated into the integrated circuit structure 900, and the metallization stack 919 can be used to route information-carrying signals from the conductive contacts 936 to transistors 940 and any other components integrated into the integrated circuit structure 900. Put another way, the routing of power and ground signals to the transistors 940 can be separated (via a back-side or bottom-side metallizaton stack and TSVs) from the routing of information-carrying signals to the transistors. The power and ground signals are provided by a backside or bottom-side metallization stack and TSVs, and information-carrying signals are provided by a topside metallization stack (e.g., metallization stack 919).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

FIG. 11 is a cross-sectional view of an integrated circuit device assembly 1100 that may include any of the embodiments disclosed herein. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and a second face 1142 of the circuit board 1102, the second face 1142 opposing the first face 1140. Generally, components may be disposed on either or both of the first face 1140 and the second face 1142 of the circuit board 1102. Any of the integrated circuit components discussed below with reference to the integrated circuit device assembly 1100 may take the form of any suitable ones of the embodiments of the microelectronic assemblies disclosed herein.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 1102. In other embodiments, the circuit board 1102 may be a non-PCB substrate.

The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102 and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.) The coupling components 1116 may serve as the coupling components illustrated or described for any substrate assembly or substrate assembly components described herein (e.g., integrated circuit components), as appropriate.

The package-on-interposer structure 1136 may include an integrated circuit component 1120 coupled to an interposer 1104. The interposer 1104 may provide an intervening substrate used to bridge the circuit board 1102 and the integrated circuit component 1120. The integrated circuit component 1120 is coupled to the interposer 1104 by coupling components 1118. The coupling components 1118 may take any suitable form, such as the forms discussed above with reference to the coupling components 1116. Although FIG. 11 shows just one integrated circuit component attached to the interposer, multiple integrated circuit components may be coupled to the interposer 1104. Additional interposers may be coupled to the interposer 1104.

The integrated circuit component 1120 may be a packaged or unpacked integrated circuit product that includes one or more integrated circuit dies (e.g., the die 802 of FIG. 8, a die comprising the integrated circuit structure 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider or narrower pitch or reroute a connection to a different connection. For example, the interposer 1104 may couple coupling components 1118 having a first pitch to coupling components 1116 having a wider pitch than the first pitch. In the embodiment illustrated in FIG. 11, the integrated circuit component 1120 and the circuit board 1102 are attached to opposing sides of the interposer 1104. In other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias, including but not limited to through hole vias 1110-1 (that extend from a first face 1150 of the interposer 1104 to a second face 1154 of the interposer 1104), blind vias 1110-2 (that extend from the first face 1150 or the second face 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

In some embodiments the interposer 1104, as well as the circuit board 1102, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 1104 or circuit board 1102 to the glass layer. The glass layer can comprise through-glass vias (TGVs) that extend through the glass layer to provide electrically conductive paths through the glass core, glass substrate, or glass layer.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 further includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include any of the microelectronic assemblies disclosed herein. For example, any suitable ones of the components of the electrical device 1200 may include one or more of the integrated circuit device assembly 1100, integrated circuit component 1120, or integrated circuit structure 900, integrated circuit dies 802 disclosed herein, and may be arranged in any of the microelectronic assemblies disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the one or more processor units 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 1200, a first one of the one or more processor units 1202 can be heterogeneous or asymmetric to a second one of the one or more processor units 1202 in the electrical device 1200. There can be a variety of differences between the one or more processor units 1202 in a system in terms of a spectrum of metrics of merit including architectural, microarchitectural, thermal, power consumption characteristics, and the like. These differences can effectively manifest themselves as asymmetry and heterogeneity among the one or more processor units 1202 in the electrical device 1200.

In some embodiments, the electrical device 1200 may include a communication component 1212. For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). In some embodiments, the electrical device 1200 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such as speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System device (GNSS) (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner.

As used herein, “connected” indicates that elements are in direct physical or electrical contact with each other and “coupled” indicates elements cooperate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, layers, faces, or features that are referred to as being substantially parallel can refer to layers, faces, or features that are within 2-5 degrees of being parallel with each other, and layers, faces, or features that are referred to as being substantially perpendicular to each other can refer to features that are within +/−15 degrees of being perpendicular to each other.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the phrase “electrically coupled” refers to the presence of one or more electrically conductive paths between components that are recited as being electrically coupled.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

As used in this application and the claims, a list of items joined by the term “and/or” can mean any combination of the listed items. For example, the phrase “A and/or B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual [of]” or “respective [of]” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus, comprising: a substrate material comprising an oxide; a first layer overlaid on the substrate material, the first layer comprising transition metal atoms and chalcogen atoms, the first layer has an upper surface and a lower surface; and a metal layer overlaid directly on the upper surface; wherein the metal layer includes ruthenium; wherein the upper surface and the metal layer form an interface; and wherein the interface is abrupt, defined as having no voids and no carbon atoms.

Example 2 includes the subject matter of Example 1, wherein the first layer is a two-dimensional (2D) material.

Example 3 includes the subject matter of Example 1 or Example 2, wherein the first layer is between 1.6 to 2.1 nanometers thick +/−10%.

Example 4 includes the subject matter of Example 1 or Example 2, wherein the first layer is less than 4 nanometers thick +/−10%.

Example 5 includes the subject matter of any one of Examples 1-4, wherein the transition metal atoms comprise molybdenum or tungsten.

Example 6 includes the subject matter of any one of Examples 1-4, wherein the first layer comprises Tungsten diselenide (WSe2), Molybdenum diselenide (MoS2), Molybdenum ditelluride (MoTe2), Tungsten disulfide (WS2).

Example 7 includes the subject matter of Example 1, wherein: the metal layer is defined by at least a first sublayer of a first metal and a second sublayer; wherein the second sublayer comprises the ruthenium; wherein the interface includes the first sublayer and the upper surface; wherein a first region of the first sublayer has the second sublayer overlaid thereon; and wherein a second region of the first sublayer comprises an oxidized form of the first metal.

Example 8 includes the subject matter of Example 7, wherein the first region is a source or drain region and the second region is a gate region of a transistor.

Example 9 includes the subject matter of Example 7 or Example 8, wherein the first sublayer comprises hafnium (Hf).

Example 10 includes the subject matter of Example 7 or Example 8, wherein the first sublayer includes one of zirconium (Zr), tantalum (Ta), aluminum (Al), niobium (Nb), vanadium (V), or molybdenum (Mo).

Example 11 includes the subject matter of any one of Examples 7-10, wherein the first sublayer comprises a thickness of 1 nanometer +/−10%, and the ruthenium comprises a thickness of 10 nanometers +/−10%.

Example 12 includes the subject matter of any one of Examples 7-11, comprising a third sublayer overlaid on the second sublayer, the third sublayer comprises tungsten (W) with a thickness of 10 nanometers +/−10%.

Example 13 includes the subject matter of Example 12, further comprising platinum (Pt), palladium (Pd) or gold (Au) sandwiched between the second sublayer and the third sublayer.

Example 14 includes the subject matter of any one of Examples 1-13, wherein the interface further comprises antimony (Sb).

Example 15 is a field effect transistor (FET) comprising: a channel material comprising a two-dimensional (2D) material; the channel material defining a channel comprising a first source/drain region, a gate region, and a second source/drain region; a first sublayer of metal overlaid directly on the channel, such that an interface is formed between the 2D material and the first sublayer of metal does not have carbon atoms; wherein the first sublayer of metal is oxidized at the gate region; and wherein, at the first source/drain region and at the second source/drain region, a second sublayer of metal is directly overlaid on the first sublayer of metal, and a third sublayer of metal is directly overlaid on the second sublayer of metal; and wherein the second sublayer comprises ruthenium (Ru), and the third sublayer of metal comprises tungsten (W).

Example 16 includes the subject matter of Example 15, wherein the first sublayer comprises hafnium (Hf).

Example 17 includes the subject matter of Example 15, wherein the first sublayer includes one of zirconium (Zr), tantalum (Ta), aluminum (Al), niobium (Nb), vanadium (V), or molybdenum (Mo).

Example 18includes the subject matter of Example 15, wherein the first sublayer comprises a thickness of 1 nanometer +/−10%, and the second sublayer comprises a thickness of 10 nanometers +/−10%.

Example 19 includes the subject matter of Example 15, wherein the third sublayer comprises a thickness of 10 nanometers +/−10%.

Example 20 includes the subject matter of any one of Examples 15-19, wherein the channel material is 1.6 nm to 2.1 nm +/−10% thick.

Example 21 is a method comprising: growing a two-dimensional (2D) channel material on a first substrate, the 2D channel material comprising transition metal atoms and chalcogen atoms; growing a metal stack on the 2D channel material, the metal stack comprising a base metal layer and at least one upper metal layer; wherein the base metal layer is directly overlaid on the 2D channel material, thereby forming an interface between the 2D channel material and the base metal layer that excludes a carbon interlayer; applying a polymer to the metal stack; transferring the metal stack and 2D material from the first substrate to a second substrate using the polymer; wherein the second substrate includes an oxide layer; identifying, for a plurality of field effect transistors, respective gate locations in the 2D channel material; and oxidizing the 2D channel material at the respective gate locations, thereby creating a plurality of 2D transistors.

Example 22 includes the subject matter of Example 21, wherein the first substrate is sapphire.

Example 23 includes the subject matter of Example 21 or Example 22, wherein the 2D material comprises Tungsten diselenide (WSe2), Molybdenum diselenide (MoS2), Molybdenum ditelluride (MoTe2), Tungsten disulfide (WS2).

Example 24 includes the subject matter of any one of Examples 21-23, further comprising overlaying the plurality of 2D transistors with a layer comprising local interconnects.

Example 25 includes the subject matter of Example 24, further comprising singulating the plurality of 2D transistors into individual dies.

Example 26 is a method comprising: growing a two-dimensional (2D) channel material on a first substrate, the 2D channel material comprising transition metal atoms and chalcogen atoms; growing a metal stack on the 2D channel material, the metal stack comprising a base metal layer and at least one upper metal layer; wherein the base metal layer is directly overlaid on the 2D channel material, thereby forming an interface between the 2D channel material and the base metal layer that excludes a carbon interlayer; transferring the metal stack and 2D material from the first substrate to a second substrate; wherein the second substrate includes an oxide layer.

Example 27 includes the subject matter of Example 26, further comprising identifying, for a plurality of field effect transistors, respective gate locations in the 2D channel material; and oxidizing the 2D channel material at the respective gate locations, thereby creating a plurality of 2D transistors.

Example 28 includes the subject matter of Example 26, wherein a polymer or adhesive tape attached to an upper surface of the metal stack is used for the transferring.

What is claimed is:

1. An apparatus, comprising:
a substrate material comprising an oxide;
a first layer overlaid on the substrate material, the first layer comprising transition metal atoms and chalcogen atoms, the first layer has an upper surface and a lower surface;
a metal layer overlaid directly on the upper surface;
wherein the metal layer includes ruthenium; and
wherein the upper surface and the metal layer form an interface;
wherein the interface comprises the metal layer in direct contact with the upper surface, without a carbon interlayer.

2. The apparatus of claim 1, wherein the first layer is a two-dimensional (2D) material.

3. The apparatus of claim 1, wherein the first layer is between 0.7 and 2.1 nanometers thick.

4. The apparatus of claim 1, wherein the transition metal atoms comprise molybdenum (Mo) or tungsten (W).

5. The apparatus of claim 1, wherein the first layer comprises tungsten diselenide (WSe2), molybdenum diselenide (MoS2), molybdenum ditelluride (MoTe2), tungsten disulfide (WS2).

6. The apparatus of claim 1, wherein:
the metal layer is defined by at least a first sublayer of a first metal and a second sublayer of the ruthenium;
the interface includes the first sublayer and the upper surface;
a first region of the first sublayer has the second sublayer overlaid thereon; and
a second region of the first sublayer comprises an oxidized form of the first metal.

7. The apparatus of claim 6, wherein the first region is a source or drain region and the second region is a gate region of a transistor.

8. The apparatus of claim 6, wherein the first sublayer comprises hafnium (Hf).

9. The apparatus of claim 6, wherein the first sublayer includes zirconium (Zr), tantalum (Ta), aluminum (Al), niobium (Nb), vanadium (V), or molybdenum (Mo).

10. The apparatus of claim 6, wherein the first sublayer comprises a thickness of 1 nanometer +/−10%, and the ruthenium comprises a thickness of 10 nanometers +/−10%.

11. The apparatus of claim 6, comprising a third sublayer overlaid on the second sublayer, the third sublayer comprises tungsten (W) with a thickness of 10 nanometers +/−10%.

12. The apparatus of claim 11, further comprising platinum (Pt), palladium (Pd) or gold (Au) sandwiched between the second sublayer and the third sublayer.

13. The apparatus of claim 1, wherein the interface further comprises antimony (Sb).

14. A field effect transistor (FET) comprising:
a channel material comprising a two-dimensional material (2D material);
the channel material defining a channel comprising a first source/drain region, a gate region, and a second source/drain region;
a first sublayer of metal overlaid directly on the channel, such that an interface between the 2D material and the first sublayer of metal does not have carbon atoms;
wherein the first sublayer of metal is oxidized at the gate region; and
wherein, at the first source/drain region and at the second source/drain region, a second sublayer of metal is directly overlaid on the first sublayer of metal, and a third sublayer of metal is directly overlaid on the second sublayer of metal;
wherein the second sublayer comprises ruthenium (Ru), and the third sublayer of metal comprises tungsten (W).

15. The FET of claim 14, wherein the first sublayer comprises hafnium (Hf).

16. The FET of claim 14, wherein the first sublayer includes one of zirconium (Zr), tantalum (Ta), aluminum (Al), niobium (Nb), vanadium (V), or molybdenum (Mo).

17. A method comprising:
growing a two-dimensional channel material (2D channel material) on a first substrate, the 2D channel material comprising transition metal atoms and chalcogen atoms;
growing a metal stack on the 2D channel material, the metal stack comprising a base metal layer and at least one upper metal layer;
wherein the base metal layer is directly overlaid on the 2D channel material, thereby forming an interface between the 2D channel material and the base metal layer that excludes a carbon interlayer;
transferring the metal stack and 2D material from the first substrate to a second substrate;
wherein the second substrate includes an oxide layer;
identifying, for a plurality of field effect transistors, respective gate locations in the 2D channel material; and
oxidizing the 2D channel material at the respective gate locations.

18. The method of claim 17, comprising utilizing an adhesive tape or polymer for the transferring.

19. The method of claim 17 further comprising identifying, for a plurality of field effect transistors, respective gate locations in the 2D channel material; and oxidizing the 2D channel material at the respective gate locations.

20. The method of claim 17, wherein the 2D material comprises Tungsten diselenide (WSe2), Molybdenum diselenide (MoS2), Molybdenum ditelluride (MoTe2), Tungsten disulfide (WS2).
